(19) United States
(12) Patent Application Publication
(10) Pub. No.: US 2011/0061906 A1
(43) Pub. Date: Mar. 17, 2011

(54) Printed circuit board and fabrication method thereof

(75) Inventors: Min Jung Cho, Incheon (KR); Mi Sun Hwang, Suwon (KR); Jae Joon Lee, Suwon (KR); Myung Sam Kang, Hwaseong (KR)

(73) Assignee: SAMSUNG ELECTRO-MECHANICS CO., LTD., Suwon (KR)

(21) Appl. No.: 12/654,433

(22) Filed: Dec. 18, 2009

(30) Foreign Application Priority Data
Sep. 15, 2009 (KR) 10-2009-0087148

(51) Int. Cl. H05K 1/09; B05D 5/12

(52) U.S. Cl. 174/257; 427/96.9

(57) ABSTRACT

A printed circuit board (PCB) and a fabrication method thereof are disclosed. The PCB includes: a dual-layered circuit pattern formed with a desired pattern on at least one of upper and lower surfaces of an insulation base member (i.e., an insulation substrate) and having metal layers each having a different thermal expansion coefficient; and an insulating layer formed on the insulation base member to cover the circuit pattern. Because the PCB includes an anti-warping unit, a processing rate and productivity can be improved.

### CROSS-REFERENCE TO RELATED APPLICATIONS

This application claims the priority of Korean Patent Application No. 10-2009-0087148 filed on Sep. 15, 2009, in the Korean Intellectual Property Office, the disclosure of which is incorporated herein by reference.

### BACKGROUND OF THE INVENTION

1. Field of the Invention

The present invention relates to a printed circuit board and a fabrication method thereof and, more particularly, to a printed circuit board having an anti-warping unit to thereby improve a processing rate and productivity, and a fabrication method thereof.

2. Description of the Related Art

Recently, substrate assemblers and manufacturers have turned much attention to an ultra-high mounting technique in line with a semiconductor package substrate which is increasingly lighter, thinner, shorter and smaller.

In particular, with respect to a soldering process performed for electrically bonding (or electrically joining) the semiconductor package substrate and a main board, the reduction in the thickness of the substrate highlights the importance of controlling warping in the semiconductor package substrate.

Semiconductor package substrate warping in the implementation of soldering greatly affects a processing rate and productivity.

In addition, the semiconductor package substrate warping causes solder balls to fail to be formed on a solder ball pad of the semiconductor substrate during the soldering process or the solder balls formed on a semiconductor element and the semiconductor package substrate to fail to be properly bonded when the semiconductor element is mounted, possibly resulting in a problematic state in which the semiconductor element and the semiconductor package substrate are not electrically connected.

The related art semiconductor package substrate generally includes a package area including a semiconductor element mounting part and an outer layer circuit pattern and a dummy area surrounding the package area.

The related art semiconductor package substrate improves warping by adjusting the thickness of the outer layer circuit pattern of the package area or the thickness of the solder resist layer of the dummy area such that overall balance within the semiconductor package substrate is maintained.

However, as the thickness of a copper clad laminate used as an inner layer core is reduced, the degree warping generation in the related art semiconductor package substrate increases, so it is difficult to improve the warping of the semiconductor package substrate by simply adjusting the thickness of the outer layer circuit pattern of the package area or the thickness of the solder resist layer of the dummy area.

### SUMMARY OF THE INVENTION

An aspect of the present invention provides a printed circuit board (PCB) having an anti-warping unit to improve a processing rate and productivity, and a fabrication method thereof.

According to an aspect of the present invention, there is provided a printed circuit board (PCB) including: a dual-layered circuit pattern formed with a desired pattern on at least one of upper and lower surfaces of an insulation base member (i.e., an insulation substrate) and having metal layers each having a different thermal expansion coefficient; and an insulating layer formed on the insulation base member to cover the circuit pattern.

The circuit pattern may be provided on the upper surface of the insulation base member and include a first conductive layer formed on the insulation base member and having a first thermal expansion coefficient and a second conductive layer formed on the first conductive layer and having a second thermal expansion coefficient greater than the first thermal expansion coefficient.

The circuit pattern may be provided on the upper surface of the insulation base member and include a second conductive layer formed on the insulation base member and having a second thermal expansion coefficient and a first conductive layer formed on the second conductive layer and having a first thermal expansion coefficient smaller than the second thermal expansion coefficient.

The circuit pattern may be provided on both of the upper and lower surfaces of the insulation base member, and the circuit pattern provided on the upper surface of the insulation base member may include a first conductive layer formed on the insulation base member and having a first thermal expansion coefficient and a second conductive layer formed on the first conductive layer and having a second thermal expansion coefficient greater than the first thermal expansion coefficient, and the circuit pattern provided on the lower surface of the insulation base member may include a second conductive layer formed on the insulation base member and having a second thermal expansion coefficient and a first conductive layer formed on the second conductive layer and having a first thermal expansion coefficient smaller than the second thermal expansion coefficient.

The circuit pattern may be provided on both of the upper and lower surfaces of the insulation base member, and the circuit pattern provided on the upper surface of the insulation base member may include a second conductive layer formed on the insulation base member and having a second thermal expansion coefficient and a first conductive layer formed on the second conductive layer and having a first thermal expansion coefficient smaller than the second thermal expansion coefficient, and the circuit pattern provided on the lower surface of the insulation base member may include a first conductive layer formed on the insulation base member and having a first thermal expansion coefficient and a second conductive layer formed on the first conductive layer and having a second thermal expansion coefficient greater than the first thermal expansion coefficient.

The first conductive layer may be made of invar or nickel, and the second conductive layer may be made of copper or a copper alloy.

The insulating layer may be a solder resist patterned to expose the circuit pattern.

The PCB may further include a through hole formed to penetrate the insulation base member or at least one surface of the insulating layer.

According to another aspect of the present invention, there is provided a method for fabricating a printed circuit board (PCB), including: forming a dual-layered circuit pattern with a desired pattern on at least one of upper and lower surfaces of an insulation base member and having metal layers each having a different thermal expansion coefficient; and forming an insulating layer on the insulation base member to cover the circuit pattern.

The circuit pattern may be provided on the upper surface of the insulation base member and include a first conductive layer formed on the insulation base member and having a first thermal expansion coefficient and a second conductive layer formed on the first conductive layer and having a second thermal expansion coefficient greater than the first thermal expansion coefficient.

The circuit pattern may be provided on the upper surface of the insulation base member and include a second conductive layer formed on the insulation base member and having a second thermal expansion coefficient and a first conductive layer formed on the second conductive layer and having a first thermal expansion coefficient smaller than the second thermal expansion coefficient.

The circuit pattern may be provided on both of the upper and lower surfaces of the insulation base member, and the circuit pattern provided on the upper surface of the insulation base member may include a first conductive layer formed on the insulation base member and having a first thermal expansion coefficient and a second conductive layer formed on the first conductive layer and having a second thermal expansion coefficient greater than the first thermal expansion coefficient, and the circuit pattern provided on the lower surface of the insulation base member may include second conductive layer formed on the insulation base member and having a second thermal expansion coefficient and a first conductive layer formed on the second conductive layer and having a first thermal expansion coefficient smaller than the second thermal expansion coefficient.

The circuit pattern may be provided on both of the upper and lower surfaces of the insulation base member, and the circuit pattern provided on the upper surface of the insulation base member may include a second conductive layer formed on the insulation base member and having a second thermal expansion coefficient and a first conductive layer formed on the second conductive layer and having a first thermal expansion coefficient smaller than the second thermal expansion coefficient, and the circuit pattern provided on the lower surface of the insulation base member may include a first conductive layer formed on the insulation base member and having a first thermal expansion coefficient and a second conductive layer formed on the first conductive layer and having a second thermal expansion coefficient greater than the first thermal expansion coefficient.

The first conductive layer may be made of invar or nickel, and the second conductive layer may be made of copper or a copper alloy.

The insulating layer may be a solder resist patterned to expose the circuit pattern.

The method may further include: forming a through hole penetrating the insulation base member or at least one surface of the insulating layer.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1a and 1b are schematic sectional views showing printed circuit boards (PCBs) with circuit patterns according to a first exemplary embodiment of the present invention;

FIGS. 2a and 2b are schematic sectional views showing printed circuit boards (PCBs) with circuit patterns according to a second exemplary embodiment of the present invention;

FIG. 3 is a schematic sectional view showing a printed circuit board (PCB) with circuit patterns according to a third exemplary embodiment of the present invention;

FIGS. 4a to 4e are sectional views sequentially showing the process of forming the PCB according to the first exemplary embodiment of the present invention; and

FIGS. 5a to 5p are sectional views sequentially showing the process of forming the PCB according to the third exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

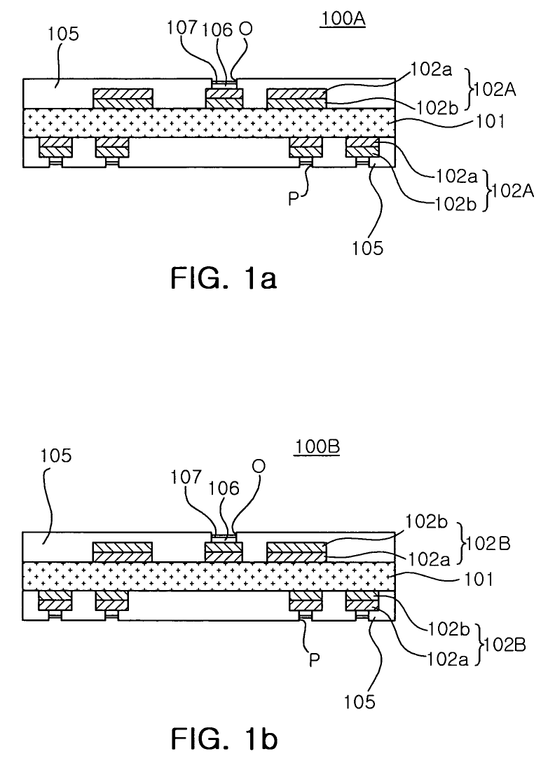

A printed circuit board (PCB) according to exemplary embodiments of the present invention will now be described with reference to FIGS. 1 to 3.

FIGS. 1a and 1b are schematic sectional views showing printed circuit boards (PCBs) with circuit patterns according to a first exemplary embodiment of the present invention. In the following description, a dual-layered PCB having circuit patterns will be taken as an example of the PCB according to the first exemplary embodiment of the present invention.

With reference to FIGS. 1a and 1b, PCBs 100A and 100B according to the first exemplary embodiment of the present invention, respectively, include dual-layered circuit patterns 102A and 102B formed so as to have a desired pattern on upper and lower surfaces of an insulation base member 101 and having metal layers each having a different thermal expansion coefficient, and an insulating layer 105 formed on the insulation base member 101 to cover the circuit patterns 102A and 102B.

Here, the PCB 100A is used as an upper substrate of a package on package (POP) substrate. The circuit pattern 102A is provided on both the upper and lower surfaces of the insulation base member 101. The circuit pattern 102A provided on the upper surface of the insulation base member 101 includes a second conductive layer 102b formed on the insulation base member 101 and having a second thermal expansion coefficient and a first conductive layer 102a formed on the second conductive layer 102b and having a first thermal expansion coefficient smaller than the second thermal expansion coefficient, and the circuit pattern 102A provided on the lower surface of the insulation base member 101 includes a first conductive layer 102a formed on the insulation base member 101 and having a first thermal expansion coefficient and a second conductive layer 102b formed on the first conductive layer 102a and having a second thermal expansion coefficient greater than the first thermal expansion coefficient.

With reference to FIG. 1b, the PCB 100B is used as a lower substrate of a package on package (POP) substrate. The circuit pattern 102B is provided on both the upper and lower surfaces of the insulation base member 101. The circuit pattern 102B provided on the upper surface of the insulation base member 101 includes a first conductive layer 102a formed on the insulation base member 101 and having a first thermal expansion coefficient and a second conductive layer 102b formed on the first conductive layer 102a and having a second thermal expansion coefficient greater than the first thermal expansion coefficient, and the circuit pattern 102A provided on the lower surface of the insulation base member 101 includes a second conductive layer 102b formed on the insulation base member 101 and having a second thermal expansion coefficient and a first conductive layer 102a formed on the second conductive layer 102b and having a first thermal expansion coefficient smaller than the first thermal expansion coefficient.

The circuit patterns 102A and 102B according to the first exemplary embodiment of the present invention may be formed of any metal so long as it has properties allowing it to constitute the first conductive layer 102a having the first thermal expansion coefficient or the second conductive layer 102b having the second thermal expansion coefficient greater than the first thermal expansion coefficient. For example, the circuit patterns 102A and 102B according to the first exemplary embodiment of the present invention may include the first conductive layer 102a made of invar or nickel (Ni) having a small thermal expansion coefficient, and the second conductive layer 102b made of copper or a copper alloy having a thermal expansion coefficient greater than that of invar or nickel.

In general, as the PCBs used for fabricating a semiconductor package are exposed to a high heat during each fabrication process, the PCBs tend to be warped (bent) upwards (i.e., having a smiling shape when viewed from the side) or warped down (i.e., having a crying shape when viewed from the side).

In detail, the PCB mounted on the upper package substrate demonstrates behavior wherein it is warped in a smiling shape at room temperature and warped in a crying shape at a high temperature. In contrast to the behavior of the upper package substrate, the PCB mounted on the lower package substrate demonstrates behavior wherein it is warped in a crying shape at room temperature and warped in a smiling shape at a high temperature.

Thus, in order to prevent the PCBs from being warped while they undergo a high temperature process or a reflow process during the semiconductor package fabrication process, the PCB mounted on the upper package substrate is configured to have the circuit pattern formed of a metal having a small thermal expansion coefficient and a metal having a large thermal expansion coefficient, which are installed such that the former (i.e., the metal having a small thermal expansion coefficient) is positioned as the surface on which a semiconductor device is to be mounted, and conversely, the PCB mounted on the lower package substrate is configured to have the circuit pattern formed of a metal having a large thermal expansion coefficient and a metal having a small thermal expansion coefficient, which are positioned such that the former (i.e., metal having a large thermal expansion coefficient) is positioned as the surface on which the semiconductor device is to be mounted, whereby stress generated due to the warping behaviors in the different directions is canceled out to maintain the PCBs in a horizontal state, and accordingly, the warping phenomenon of the PCBs can be significantly reduced.

Here, the insulating layers 105 are formed on the insulation base member 101 and have openings O and P exposing the circuit patterns 102A and 102B so as to be bonded with solder balls. The insulating layers 105 may be formed as a patterned solder resist. Here, a gold-plated layer 107 is formed in each of the openings O and P for a connection with a semiconductor element or solder balls. Also, in order to enhance adhesive properties with gold, preferably, a nickel layer 106 is thinly plated and the gold-plated layer 107 is formed on the nickel layer 106.

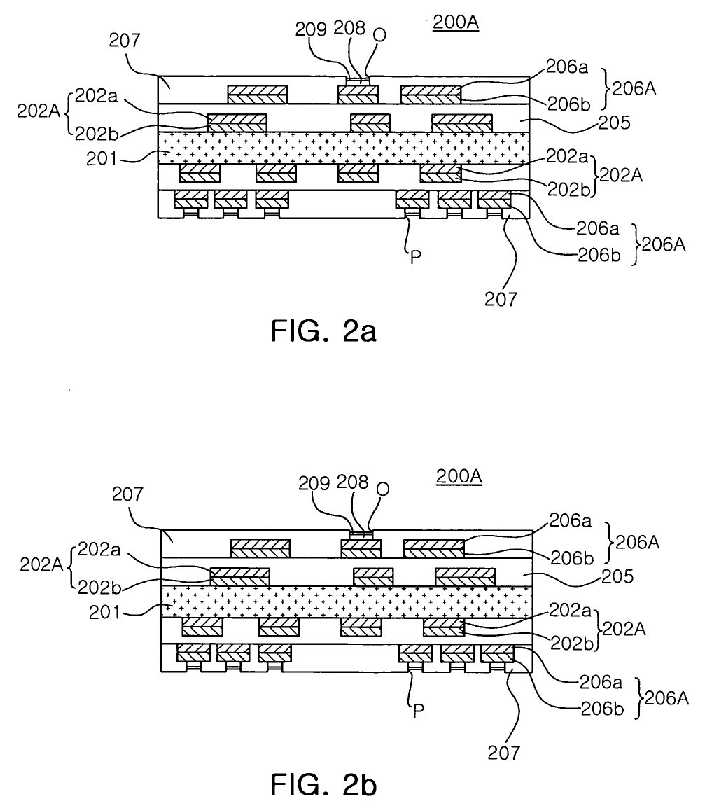

FIGS. 2a and 2b are schematic sectional views showing PCBs with circuit patterns according to a second exemplary embodiment of the present invention. The PCBs 200A and 200B according to the second exemplary embodiment of the present invention is a four-layered PCB with circuit patterns.

With reference to FIG. 2a, the PCB 200A according to the second exemplary embodiment of the present invention includes dual-layered circuit patterns 202A and 206A formed to have a desired pattern on upper and lower surfaces of an insulation base member 201 and having metal layers each having a different thermal expansion coefficient, and insulating layers 205 and 207 formed on the insulation base member 201 to cover the circuit patterns 202A and 206A.

Unlike the first exemplary embodiment, the circuit pattern 206A and the insulating layers 207 are formed on the insulating layer 205 which is not patterned.

Here, the PCB 200A is used as an upper substrate of a package on package (POP) substrate. The circuit patterns 202A and 206A are provided with a desired pattern on both the upper and lower surfaces of the insulation base member 201. The circuit patterns 202A and 206A provided on the upper surface of the insulation base member 201 include second conductive layers 202b and 206b formed on the insulation base member 201 and having a second thermal expansion coefficient and first conductive layers 202a and 206a formed on the second conductive layers 202b and 206b and having a first thermal expansion coefficient smaller than the second thermal expansion coefficient, and the circuit patterns 202A and 206A provided on the lower surface of the insulation base member 201 include first conductive layers 202a and 206a formed on the insulation base member 201 and having a first thermal expansion coefficient and second conductive layers 202b and 206b formed on the first conductive layers 202a and 206a and having a second thermal expansion coefficient greater than the first thermal expansion coefficient.

Like those of the first exemplary embodiment, the insulating layers 207 have openings O and P exposing the circuit patterns 206A so as to be bonded with solder balls. The insulating layers 207 may be formed as a patterned solder resist. Here, a gold-plated layer 209 is formed in each of the openings O and P for a connection with a semiconductor element or solder balls. Also, in order to enhance adhesive properties with gold, preferably, a nickel layer 208 is thinly plated and the gold-plated layer 209 is formed on the nickel layer 208.

With reference to FIG. 2b, the PCB 200B is used as a lower substrate of the package on package (POP) substrate. The circuit patterns 202B and 206B are provided with a desired pattern on both the upper and lower surfaces of the insulation base member 201. The circuit patterns 202B and 206B provided on the upper surface of the insulation base member 201 include first conductive layers 202a and 206a formed on the insulation base member 201 and having a first thermal expansion coefficient and second conductive layers 202b and 206b formed on the first conductive layers 202a and 206a and having a second thermal expansion coefficient greater than the first thermal expansion coefficient, and the circuit patterns 202B and 206B provided on the lower surface of the insulation base member 201 include second conductive layers 202b and 206b formed on the insulation base member 201 and having a second thermal expansion coefficient and first conductive layers 202a and 206a formed on the second conductive layers 202b and 206b and having a first thermal expansion coefficient smaller than the second thermal expansion coefficient.

Like those of the first exemplary embodiment, the insulating layers 207 have openings O and P exposing the circuit patterns 206A so as to be bonded with solder balls. The insulating layers 207 may be formed as patterned solder resists. Here, a gold-plated layer 209 is formed in each of the openings O and P for a connection with a semiconductor element or solder balls. Also, in order to enhance adhesive properties with gold, preferably, a nickel layer 208 is thinly plated and the gold-plated layer 209 is formed on the nickel layer 208.

In general, as the PCBs for fabricating a semiconductor package are exposed to a high heat during each fabrication process, the PCBs tend to be warped (bent) up (i.e., having a smiling shape when viewed from the side) or warped down (i.e., having a crying shape when viewed from the side).

In detail, the PCB mounted on the upper package substrate demonstrates behavior wherein it is warped in a smiling shape at room temperature and warped in a crying shape at a high temperature. In contrast to the behavior of the upper package substrate, the PCB mounted on the lower package substrate demonstrates behavior wherein it is warped in a crying shape at room temperature and warped in a smiling shape at a high temperature.

Thus, in order to prevent the PCBs from being warped while they undergo a high temperature process or a reflow process during the semiconductor package fabrication process, the PCB mounted on the upper package substrate is configured to have the circuit pattern formed of a metal having a small thermal expansion coefficient and a metal having a large thermal expansion coefficient, which are installed such that the former (i.e., the metal having a small thermal expansion coefficient) is positioned on the surface on which a semiconductor device is to be mounted, and conversely, the PCB mounted on the lower package substrate is configured to have the circuit pattern formed of a metal having a large thermal expansion coefficient and a metal having a small thermal expansion coefficient, which are positioned such that the former (i.e., metal having a large thermal expansion coefficient) is positioned on the surface on which the semiconductor device is to be mounted, whereby stress generated due to the warping behaviors in the different directions is canceled out to maintain the PCBs in a horizontal state, and accordingly, the warping phenomenon of the PCBs can be significantly reduced.

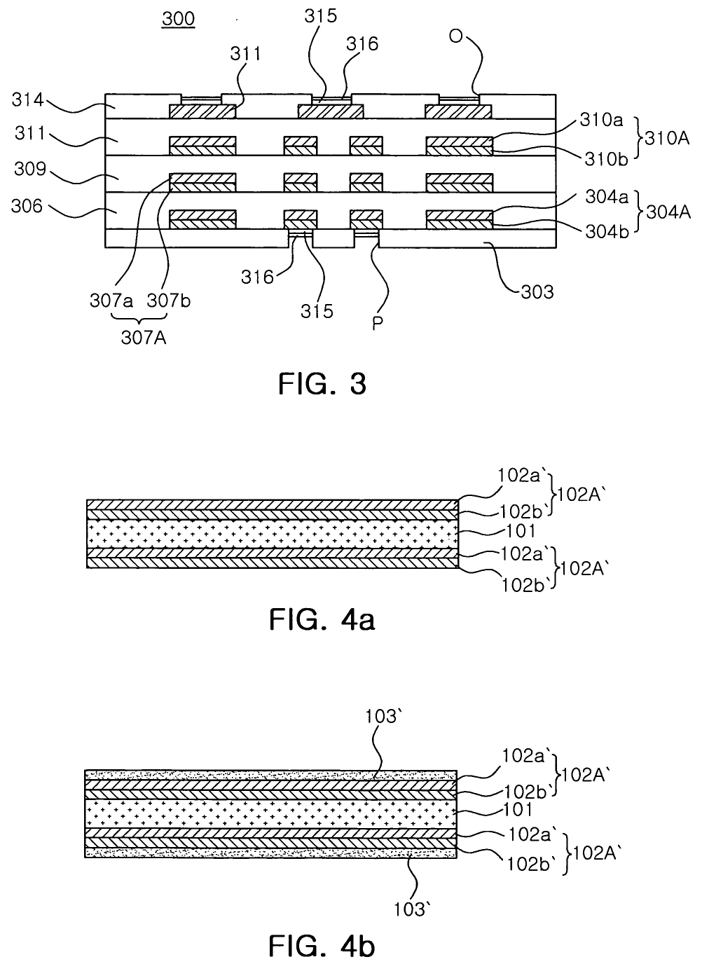

FIG. 3 is a schematic sectional view showing a printed circuit board (PCB) with circuit patterns according to a third exemplary embodiment of the present invention. The PCB according to the third exemplary embodiment of the present invention is a four-layered PCB with circuit patterns.

Unlike the four-layered PCB according to the second exemplary embodiment of the present invention, the PCB 300 according to the third exemplary embodiment of the present invention is configured such that circuit patterns are formed only on one side of insulation base members, rather than formed on both sides of the insulation base members.

With reference to FIG. 3, in the PCB 300, desired patterns are formed on an insulating layer 303 or on one surface of each of the insulation base members 306, 309, and 311. That is, the PCB 300 includes dual-layered circuit patterns 304A, 307A, and 310A with metal layers each having a different thermal expansion coefficient and insulation base members 306, 309, 311, and 314 covering the circuit patterns 304A, 307A, and 310A.

Here, the PCB 300 is used as a lower substrate of the package on package (POP) substrate. The circuit patterns 304A, 307A, and 310A are provided on the insulating layer 303 or on the insulation base members 306, 309, and 311, and include second conductive layers having a second thermal expansion coefficient formed on the insulation base members 306, 309, and 311 and first conductive layers having a first thermal expansion coefficient formed on the second conductive layers. When the PCB 300 is used as a lower substrate of the POP substrate, the second and first conductive layers may be formed conversely.

Like those of the former exemplary embodiment, the insulating layers 303 and 314, constituting the uppermost layers, have openings O and P, and a gold-plated layer 316 is formed in each of the openings O and P for a connection with solder balls. Also, in order to enhance adhesive properties with gold, preferably, a nickel layer 315 is thinly plated and the gold-plated layer 316 is formed on the nickel layer 316.

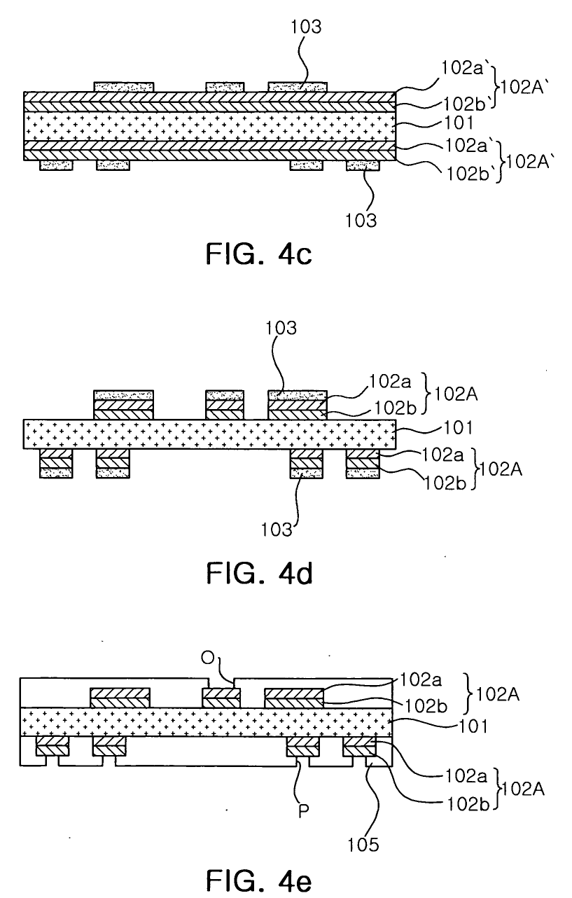

The process of forming the PCB according to the first exemplary embodiment of the present invention will now be described with reference to FIGS. 4a to 4e.

As shown in FIG. 4a, in order to form desired circuit patterns on the upper and lower surfaces of the insulation base member 101, two-storied (dual) metal layers 102A′ (102a′ and 102b′) each having a different thermal expansion coefficient are formed.

Next, as shown in FIG. 4b, a solder resist 103′ is formed on the two-storied metal layers 102A′ (102a′ and 102b′) each having a different thermal expansion coefficient.

Then, as shown in FIG. 4c, the solder resist 103′ is exposed and developed to form a solder resist pattern 103 having a desired pattern. Thereafter, as shown in FIG. 4d, the two-storied metal layers 102A′ (102a′ and 102b′) each having a different thermal expansion coefficient are etched to form the circuit pattern 102A, on the upper portion of the insulation base member 101, including the second conductive layer 102b having the second thermal expansion coefficient formed on the insulation base member 101 and the first conductive layer 102a formed on the second conductive layer 102b and having the first thermal expansion coefficient smaller than the second thermal expansion coefficient, and the circuit pattern 102A, on the lower portion of the insulation base member 101, including the first conductive layer 102a having the first thermal expansion coefficient formed on the insulation base member 101 and the second conductive layer 102b formed on the first conductive layer 102a and having the second thermal expansion coefficient greater than the first thermal expansion coefficient.

Subsequently, as shown in FIG. 4e, the solder resist 105 is formed on the circuit pattern 102A. The solder resist 105 has openings O and P. A gold-plated layer 107 is formed in each of the openings O and P for a connection with a semiconductor element or solder balls. Also, in order to enhance adhesive properties with gold, preferably, the nickel layer 106 is thinly plated and the gold-plated layer 107 is formed on the nickel layer 106.

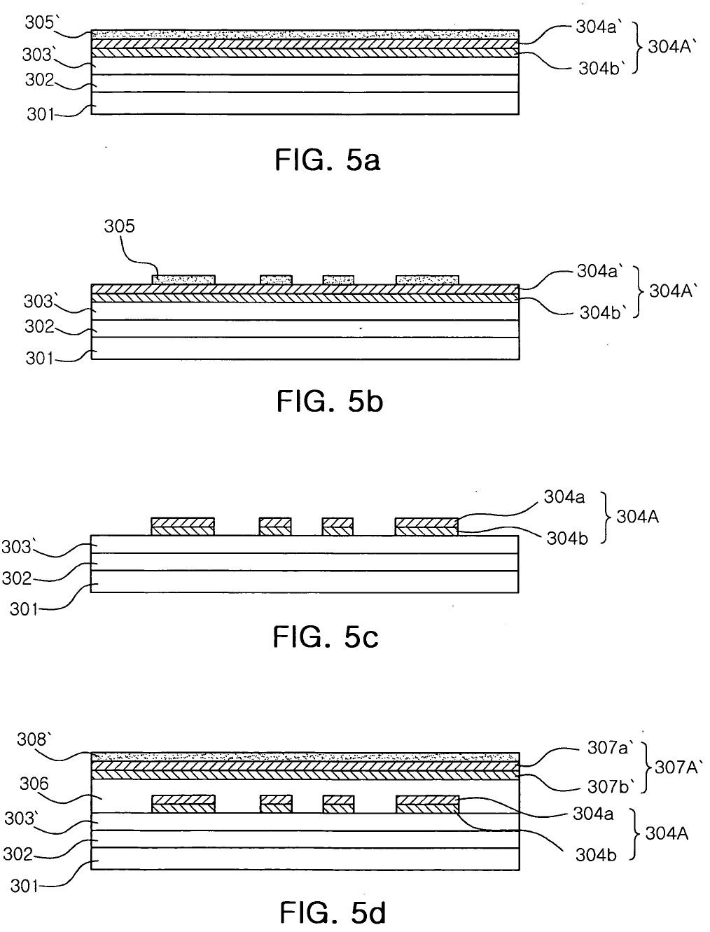

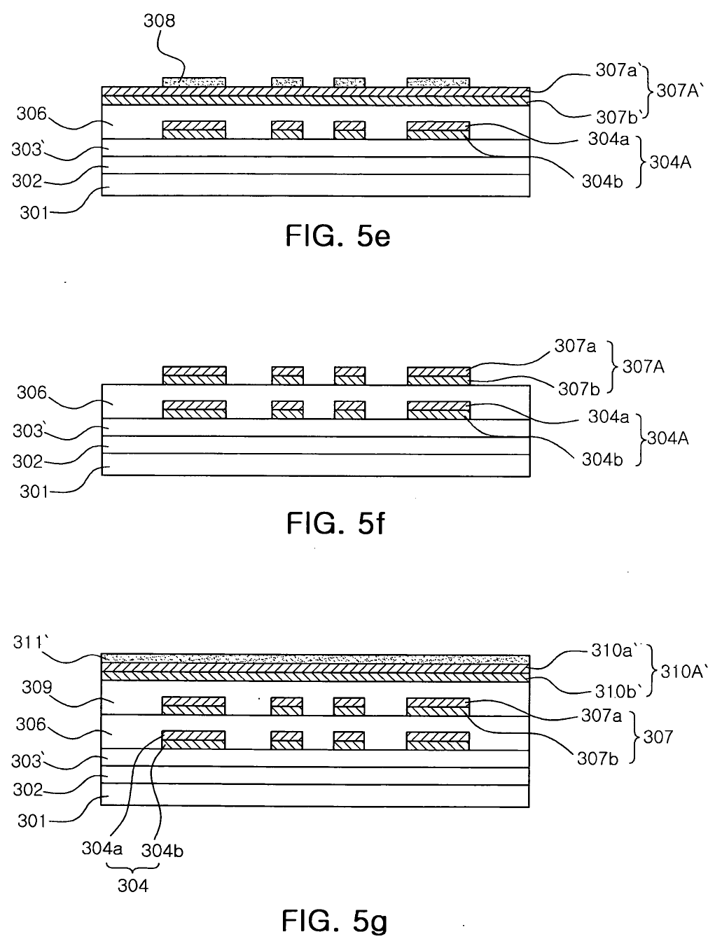

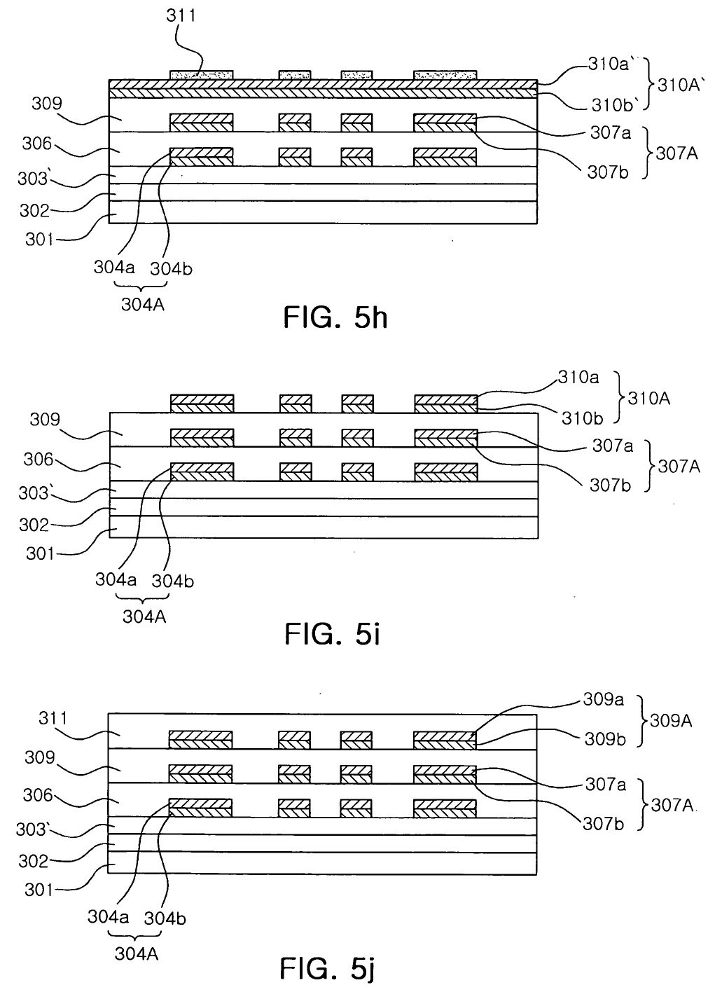

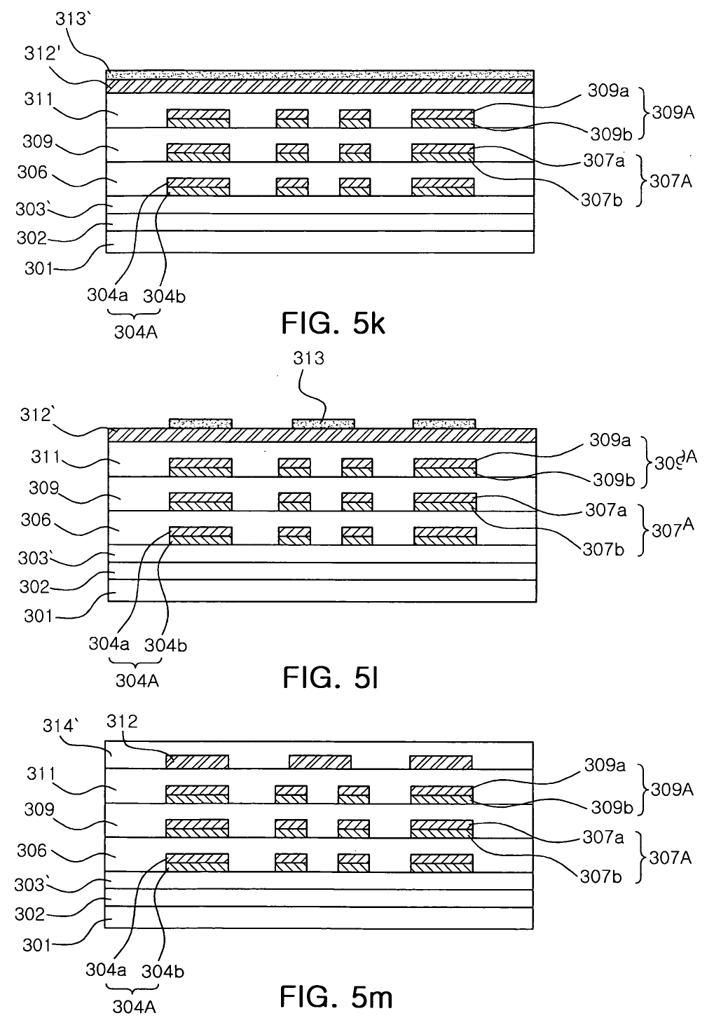

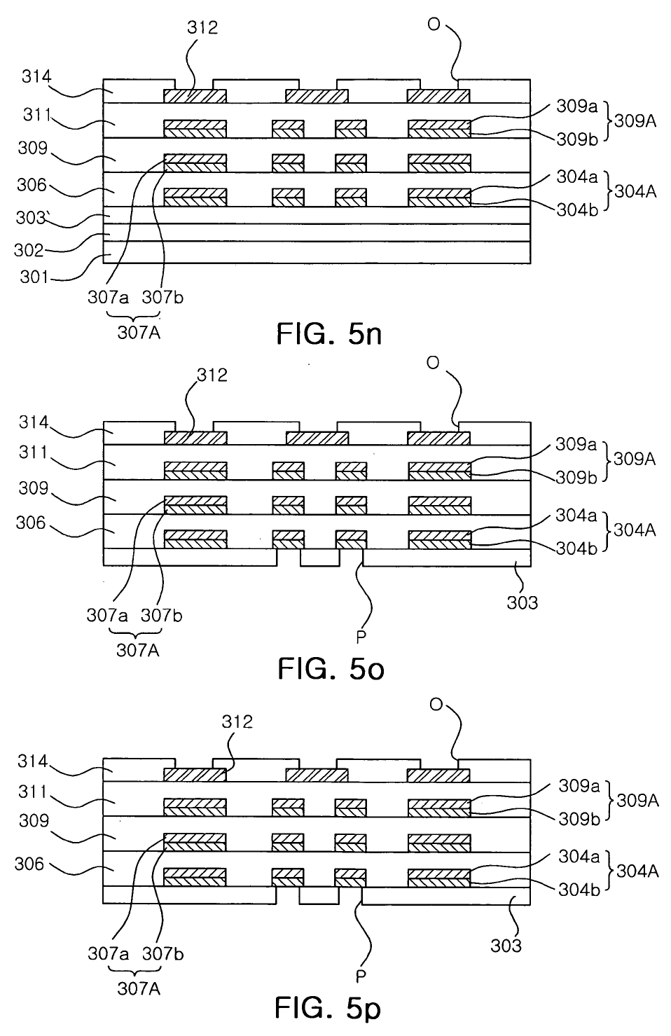

The process of forming the PCB according to the third exemplary embodiment of the present invention will now be described with reference to FIGS. 5a to 5p.

As shown in FIG. 5a, first, two-storied metal layers 304A′ (304a′ and 304b′), each having a different thermal expansion coefficient, are formed on a carrier 301 with a copper layer 302 and a solder resist 303′ sequentially stacked thereon. Next, a solder resist 305′ is coated on the two-storied metal layer 304A′ (304a′ an 304b′), each having a different thermal expansion coefficient, to form a solder resist pattern 305 having a desired pattern as shown in FIG. 5b.

And then, as shown in FIG. 5c, the two-storied metal layers 305A′ (304a′ and 304b′), each having a different thermal expansion coefficient, are etched to form the circuit pattern 304A made up of a second conductive layer 304b formed on the carrier 301 and having a second thermal expansion coefficient and a first conductive layer 304a formed on the second conductive layer 304b and having a first thermal expansion coefficient smaller than the second thermal expansion coefficient. Thereafter, the solder resist pattern 305 is removed.

Subsequently, as shown in FIG. 5d, the insulating layer 306 (e.g., a pre-preg) is formed on the circuit pattern 304A, and two-storied metal layers 307A′ (307a′ and 307b′), each having a different thermal expansion coefficient, are then formed on the insulating layer 306. Then, a solder resist 308′ is coated on the two-storied metal layers 307A′ (307a′ and 307b′), each having a different thermal expansion coefficient, to form a solder resist pattern 308 having a desired pattern.

Thereafter, as shown in FIG. 5f, the two-storied metal layers 307A′ (307a′ and 307b′), each having a different thermal expansion coefficient, are etched to form the circuit pattern 307A made up of the second conductive layer 307b formed on the insulating layer 306 and having the second thermal expansion coefficient and the first conductive layer 307a formed on the second conductive layer 307b and having the first thermal expansion coefficient smaller than the second thermal expansion coefficient.

As shown in FIG. 5g, the insulating layer 309 (e.g., a pre-preg) is formed on the circuit pattern 307A, and two-storied metal layers 310A′ (310a′ and 310b′), each having a different thermal expansion coefficient, are coated on the insulating layer 309 to form a solder resist pattern 311 having a desired pattern as shown in FIG. 5h.

And then, as shown in FIG. 5i, the two-storied metal layers 310A′ (310a′ and 310b′), each having a different thermal expansion coefficient, are etched to form the circuit pattern 310A made up of the second conductive layer 310b formed on the insulating layer 309 and having the second thermal expansion coefficient and the first conductive layer 310a formed on the second conductive layer 310b and having the first thermal expansion coefficient smaller than the second thermal expansion coefficient. Thereafter, the solder resist pattern 311 is removed.

Next, as shown in FIG. 5j, the insulating layer 311 (e.g., a pre-preg) is formed on the circuit pattern 310A, a metal layer 312′ and a solder resist 313′ are coated on the insulating layer 311 as shown in FIG. 5k, and a solder resist pattern 313 having a desired pattern is then formed as shown in FIG. 51.

Then, as shown in FIG. 5m, the metal layer 312′ is etched to form a metal layer 312, which is then connected with an external element. Next, a solder resist 314′ is coated on the metal layer 312 to form a solder resist pattern 314 having a desired pattern as shown in FIG. 5n.

Thereafter, as shown in FIG. 5o, the carrier 301 and the copper layer 302 are removed, the solder resist 303′ is patterned to form a solder resist pattern 303 having a desired pattern, which is then connected with an external element.

The solder resists 303 and 314 have the openings O and P, and a gold-plated layer 316 is formed in each of the openings O and P for a connection with solder balls. Also, in order to enhance adhesive properties with gold, preferably, the nickel layer 315 is thinly plated and the gold-plated layer 316 is formed on the nickel layer 315.

In general, as the PCBs for fabricating a semiconductor package are exposed to a high heat during each fabrication process, the PCBs tend to be warped (bent) up (i.e., having a smiling shape when viewed from the side) or warped down (i.e., having a crying shape when viewed from the side).

In detail, the PCB mounted on the upper package substrate demonstrates behavior wherein it is warped in a smiling shape at room temperature and warped in a crying shape at a high temperature. In contrast to the behavior of the upper package substrate, the PCB mounted on the lower package substrate demonstrates behavior wherein it is warped in a crying shape at room temperature and warped in a smiling shape at a high temperature.

Thus, in order to prevent the PCBs from being warped while they undergo a high temperature process or a reflow process during the semiconductor package fabrication process, the PCB mounted on the upper package substrate is configured to have the circuit pattern formed of a metal having a small thermal expansion coefficient and a metal having a large thermal expansion coefficient, which are installed such that the former (i.e., the metal having a small thermal expansion coefficient) comes on the surface on which a semiconductor device is to be mounted, and conversely, the PCB mounted on the lower package substrate is configured to have the circuit pattern formed of a metal having a large thermal expansion coefficient and a metal having a small thermal expansion coefficient, which are positioned such that the former (i.e., metal having a large thermal expansion coefficient) is positioned on the surface on which the semiconductor device is to be mounted, whereby stress generated due to the warping behaviors in the different directions is canceled out to maintain the PCBs in a horizontal state, and accordingly, the warping phenomenon of the PCBs can be significantly reduced.

In the entire exemplary embodiments, the PCB may further include a through hole formed to penetrate the insulation base member or at least one side of the insulating layer.

As described above, because the PCB according to the exemplary embodiments of the present invention has the anti-warping unit, the processing rate and productivity can be improved.

Also, because the presence of the anti-warping unit disposed within the PCB according to the exemplary embodiments of the present invention leads to an improvement of the assembling characteristics, a processing time and cost can be accordingly reduced.

As set forth above, according to exemplary embodiments of the invention, because the PCB includes an anti-warping unit, a processing rate and productivity can be improved.

Also, because the assembling characteristics can be improved by having the anti-warping unit within the PCB, a processing time as well as a processing cost can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board (PCB) comprising:
a dual-layered circuit pattern formed of a desired pattern on at least one of upper and lower surfaces of an insulation base member (i.e., an insulation substrate) and having metal layers each having a different thermal expansion coefficient; and
an insulating layer formed on the insulation base member to cover the circuit pattern.

2. The printed circuit board of claim 1, wherein the circuit pattern is provided on the upper surface of the insulation base member and includes a first conductive layer formed on the insulation base member and having a first thermal expansion coefficient and a second conductive layer formed on the first conductive layer and having a second thermal expansion coefficient greater than the first thermal expansion coefficient.

3. The printed circuit board of claim 1, wherein the circuit pattern is provided on the upper surface of the insulation base member and includes a second conductive layer formed on the insulation base member and having a second thermal expansion coefficient and a first conductive layer formed on the second conductive layer and having a first thermal expansion coefficient smaller than the second thermal expansion coefficient.

4. The printed circuit board of claim 1, wherein the circuit pattern is provided on both of the upper and lower surfaces of the insulation base member, and the circuit pattern provided on the upper surface of the insulation base member comprises a first conductive layer formed on the insulation base member and having a first thermal expansion coefficient and a second conductive layer formed on the first conductive layer and having a second thermal expansion coefficient greater than the first thermal expansion coefficient, and the circuit pattern provided on the lower surface of the insulation base member comprises a second conductive layer formed on the insulation base member and having a second thermal expansion coefficient and a first conductive layer formed on the second conductive layer and having a first thermal expansion coefficient smaller than the second thermal expansion coefficient.

5. The printed circuit board of claim 1, wherein the circuit pattern is provided on both of the upper and lower surfaces of the insulation base member, and the circuit pattern provided on the upper surface of the insulation base member comprises a second conductive layer formed on the insulation base member and having a second thermal expansion coefficient and a first conductive layer formed on the second conductive layer and having a first thermal expansion coefficient smaller than the second thermal expansion coefficient, and the circuit pattern provided on the lower surface of the insulation base member comprises a first conductive layer formed on the insulation base member and having a first thermal expansion coefficient and a second conductive layer formed on the first conductive layer and having a second thermal expansion coefficient greater than the first thermal expansion coefficient.

6. The printed circuit board of claim 1, wherein the first conductive layer is made of invar or nickel, and the second conductive layer is made of copper or a copper alloy.

7. The printed circuit board of claim 1, wherein the insulating layer is solder resist patterned to expose the circuit pattern.

8. The printed circuit board of claim 1, further comprising:
a through hole formed to penetrate the insulation base member or at least one surface of the insulating layer.

9. A method for fabricating a printed circuit board (PCB), the method comprising:
forming a dual-layered circuit pattern with a desired pattern on at least one of upper and lower surfaces of an insulation base member and having metal layers each having a different thermal expansion coefficient; and
forming an insulating layer on the insulation base member to cover the circuit pattern.

10. The method of claim 9, wherein the circuit pattern is provided on the upper surface of the insulation base member and comprises a first conductive layer formed on the insulation base member and having a first thermal expansion coefficient and a second conductive layer formed on the first conductive layer and having a second thermal expansion coefficient greater than the first thermal expansion coefficient.

11. The method of claim 9, wherein the circuit pattern is provided on the upper surface of the insulation base member and includes a second conductive layer formed on the insulation base member and having a second thermal expansion coefficient and a first conductive layer formed on the second conductive layer and having a first thermal expansion coefficient smaller than the second thermal expansion coefficient.

12. The method of claim 9, wherein the circuit pattern is provided on both of the upper and lower surfaces of the insulation base member, and the circuit pattern provided on the upper surface of the insulation base member includes a first conductive layer formed on the insulation base member and having a first thermal expansion coefficient and a second conductive layer formed on the first conductive layer and having a second thermal expansion coefficient greater than the first thermal expansion coefficient, and the circuit pattern provided on the lower surface of the insulation base member comprises a second conductive layer formed on the insulation base member and having a second thermal expansion coefficient and a first conductive layer formed on the second conductive layer and having a first thermal expansion coefficient smaller than the second thermal expansion coefficient.

13. The method of claim 9, wherein the circuit pattern is provided on both of the upper and lower surfaces of the insulation base member, and the circuit pattern provided on the upper surface of the insulation base member comprises a second conductive layer formed on the insulation base member and having a second thermal expansion coefficient and a first conductive layer formed on the second conductive layer and having a first thermal expansion coefficient smaller than the second thermal expansion coefficient, and the circuit pattern provided on the lower surface of the insulation base member comprises a first conductive layer formed on the insulation base member and having a first thermal expansion coefficient and a second conductive layer formed on the first conductive layer and having a second thermal expansion coefficient greater than the first thermal expansion coefficient.

14. The method of claim 9, wherein the first conductive layer is made of invar or nickel, and the second conductive layer is made of copper or a copper alloy.

15. The method of claim 9, wherein the insulating layer is formed of solder resist patterned to expose the circuit pattern.

16. The method of claim 9, further comprising:
forming a through hole penetrating the insulation base member or at least one surface of the insulating layer.
